(19) United States
(12) Patent Application Publication
(10) Pub. No.: US 2025/0157816 A1
(43) Pub. Date: May 15, 2025

(54) METHOD OF OBTAINING NANOSCALE LINE BY USING LASER

(71) Applicant: INSTITUTE OF MICROELECTRONICS, CHINESE ACADEMY OF SCIENCES, Beijing (CN)

(72) Inventors: Jinbiao Liu, Beijing (CN); Jun Luo, Beijing (CN); Junfeng Li, Beijing (CN); Xiaobin He, Beijing (CN); Tao Yang, Beijing (CN)

(21) Appl. No.: 18/933,956

(22) Filed: Oct. 31, 2024

(30) Foreign Application Priority Data
Nov. 9, 2023 (CN) 202311490292.7

(51) Int. Cl. H01L 21/02; H01L 21/306

(52) U.S. Cl. CPC H01L 21/02678; H01L 21/02381; H01L 21/02532; H01L 21/02592; H01L 21/30604; H01L 21/30625

(57) ABSTRACT

The present disclosure relates to a method of obtaining a nanoscale line by using a laser, including: forming a dielectric layer and an amorphous silicon layer on a substrate sequentially; irradiating a mask plate by using the laser to perform a silicon crystallization in a partial region of the amorphous silicon layer, where a grain boundary of a polycrystalline silicon formed by the silicon crystallization in the partial region of the amorphous silicon layer is determined by a spacing between holes with a regular shape on the mask plate; performing a planarization process on the grain boundary of the polycrystalline silicon of the amorphous silicon layer; removing the grain boundary by using a corrosion solution to form a grain boundary trench; and obtaining the nanoscale line on the substrate by using the grain boundary trench.

### CROSS REFERENCE TO RELATED APPLICATION

This application claims priority to Chinese Patent Application No. 202311490292.7, filed on Nov. 9, 2023, the entire content of which is incorporated by reference herein in its entirety.

### TECHNICAL FIELD

The present disclosure relates to a field of semiconductor technology, and in particular to a method of obtaining a nanoscale line by using a laser.

### BACKGROUND

A line width of an integrated circuit refers to the minimum size that may be lithographed as determined by a particular process, which is generally understood as the minimum line width in a processed circuit pattern. An integration degree corresponds to the line width, i.e., the higher the integration degree, the smaller the line width. Therefore, the line width is also commonly used to represent a technical level of the integrated circuit manufacturing.

As the size of the integrated circuit continues to shrink, an advanced photolithography technology needs to be used to obtain a fine line. In the industry, a high-density nanoscale optical line is obtained by using multiple exposures or an expensive Extreme Ultra-violet (EUV) photolithography technology, which has a complex process and extremely high cost.

### SUMMARY

The embodiments of the present disclosure provide a method of obtaining a nanoscale line by using a laser, including:
forming a dielectric layer and an amorphous silicon layer on a substrate sequentially;
irradiating a mask plate by using the laser to perform a silicon crystallization in a partial region of the amorphous silicon layer, wherein a grain boundary of a polycrystalline silicon formed by the silicon crystallization in the partial region of the amorphous silicon layer is determined by a spacing between holes with a regular shape on the mask plate;
performing a planarization process on the grain boundary of the polycrystalline silicon of the amorphous silicon layer;
removing the grain boundary by using a corrosion solution to form a grain boundary trench; and
obtaining the nanoscale line on the substrate by using the grain boundary trench.

Based on a further improvement of the above-mentioned method, a material of the dielectric layer is silicon nitride.

Based on a further improvement of the above-mentioned method, a material of the substrate is silicon or silicon dioxide.

Based on a further improvement of the above-mentioned method, the performing a planarization process on the grain boundary of the polycrystalline silicon of the amorphous silicon layer includes:
depositing a silicon dioxide on the amorphous silicon layer;
removing the silicon dioxide on the polycrystalline silicon by chemical mechanical polishing; and
removing the silicon dioxide on a surface of a remaining region of the amorphous silicon layer by using an acidic corrosion solution.

Based on a further improvement of the above-mentioned method, the obtaining the nanoscale line on the substrate by using the grain boundary trench includes:
filling a silicon dioxide film on the polycrystalline silicon to cover the grain boundary trench;
removing the silicon dioxide on a surface of the polycrystalline silicon by chemical mechanical polishing or reverse etching;
removing the polycrystalline silicon by using an alkaline silicon corrosion solution and retaining the silicon dioxide filled in the grain boundary trench;
etching the dielectric layer by using the silicon dioxide in the grain boundary trench as a hard mask, and stopping the etching at a surface of the substrate; and
etching the substrate by using the silicon dioxide in the grain boundary trench and the etched dielectric layer as a hard mask, so as to obtain the nanoscale line.

Based on a further improvement of the above-mentioned method, the filling a silicon dioxide film on the polycrystalline silicon to cover the grain boundary trench includes:
filling, by using an atomic layer deposition ALD process, the silicon dioxide film on the polycrystalline silicon to cover the grain boundary trench.

Based on a further improvement of the above-mentioned method, the alkaline silicon corrosion solution is a tetramethylammonium hydroxide solution or a potassium hydroxide solution.

Based on a further improvement of the above-mentioned method, a width of the nanoscale line is less than 10 nanometers.

Based on a further improvement of the above-mentioned method, the corrosion solution is a Secco corrosion solution.

Based on a further improvement of the above-mentioned method, an energy density of the laser is in a range of 100 millijoules per square centimeter to 2 joules per square centimeter.

In the present disclosure, the above-mentioned technical solutions may be combined with each other to achieve more preferable combination solutions. Other features and advantages of the present disclosure will be set forth in the following description, and some advantages may be apparent from the description, or may be understood by implementing the present disclosure. The objectives and other advantages of the present disclosure may be achieved and obtained through the contents particularly pointed out in the description and the accompanying drawings.

### BRIEF DESCRIPTION OF THE DRAWINGS

The accompanying drawings are only used for the purpose of illustrating embodiments and are not to be construed as limiting the present disclosure. Throughout the accompanying drawings, the same reference numerals are used to represent the same components.

FIG. 1 is a schematic flowchart of a method of obtaining a nanoscale line by using a laser according to an embodiment of the present disclosure.

FIG. 2 is a process flow of a method of obtaining a nanoscale line by using a laser according to an embodiment of the present disclosure.

FIG. 3A shows an example of a grain boundary of polycrystalline silicon formed according to an embodiment of the present disclosure.

FIG. 3B shows another example of a grain boundary of polycrystalline silicon formed according to an embodiment of the present disclosure.

FIG. 3C shows a conceptual diagram of a structure after depositing silicon dioxide on an amorphous silicon layer 30 according to an embodiment of the present disclosure.

FIG. 3D shows a conceptual diagram of a structure after removing silicon dioxide on the polycrystalline silicon 70 by using a chemical mechanical polishing process according to an embodiment of the present disclosure.

FIG. 4 shows an example of a planarized grain boundary of the polycrystalline silicon according to an embodiment of the present disclosure.

FIG. 5 shows an example of a nanoscale line obtained on a substrate according to an embodiment of the present disclosure.

FIG. 6 shows a conceptual diagram of a structure after filling a silicon dioxide film on the polycrystalline silicon 70 to cover the grain boundary trench according to an embodiment of the present disclosure.

FIG. 7 shows a conceptual diagram of a structure after removing silicon dioxide on a surface of the polycrystalline silicon 70 by chemical mechanical polishing or reverse etching according to an embodiment of the present disclosure.

FIG. 8 shows a conceptual diagram of a structure after removing the polycrystalline silicon 70 by using an alkaline silicon corrosion solution according to an embodiment of the present disclosure.

FIG. 9 shows a conceptual diagram of a structure after etching the dielectric layer 20 by using the silicon dioxide in the grain boundary trench as a hard mask according to an embodiment of the present disclosure.

FIG. 10 shows a conceptual diagram of a structure after etching the substrate 10 by using the silicon dioxide in the grain boundary trench and the etched dielectric layer 20 as a hard mask to obtain the nanoscale line according to an embodiment of the present disclosure.

FIG. 11 shows a process flow of a method of obtaining a nanoscale line by using a laser according to an embodiment of the present disclosure.

Reference numerals: 10—Substrate; 20—Dielectric layer; 30—Amorphous silicon layer; 40—Mask plate; 50—Circular hole; 60—Crystalline silicon; 70—Polycrystalline silicon; 80—Fine line.

### DETAILED DESCRIPTION OF EMBODIMENTS

The preferred embodiments of the present disclosure will be described in detail below with reference to the accompanying drawings. The accompanying drawings constitute a part of the present disclosure, and the accompanying drawings along with the embodiments of the present disclosure are used to illustrate the principles of the present disclosure. However, the accompanying drawings are not intended to limit the scope of the present disclosure.

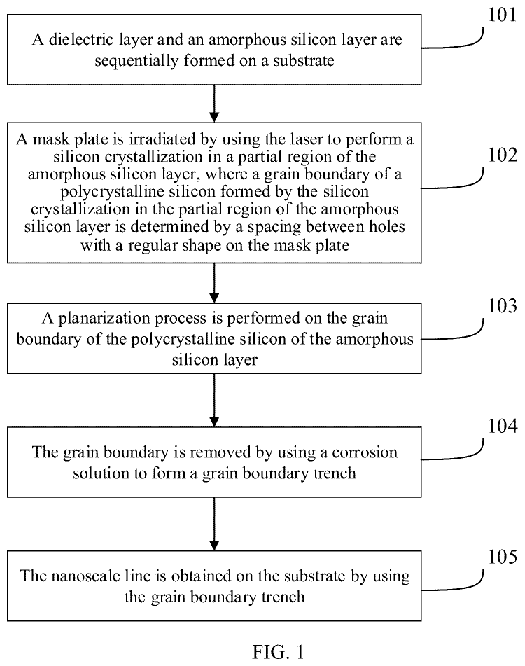

FIG. 1 is a schematic flowchart of a method of obtaining a nanoscale line by using a laser according to an embodiment of the present disclosure.

An embodiment of the present disclosure will be described with reference to FIG. 1.

As shown in FIG. 1, a method of obtaining a nanoscale line by using a laser includes Step 101 to Step 105.

Step 101: a dielectric layer and an amorphous silicon layer are sequentially formed on a substrate.

In this embodiment, a material of the substrate may be silicon or silicon dioxide. The dielectric layer may be grown on the substrate by using a Chemical Vapor Deposition (CVD) process or an Atomic Layer Deposition (ALD) process. A material of the dielectric layer may be silicon nitride. The silicon wettability of the silicon nitride material is good, which may reduce a nucleation rate in the crystallization process and promote a lateral growth.

In this embodiment, the amorphous silicon layer may be grown on the dielectric layer by using a Plasma Enhanced Chemical Vapor Deposition (PECVD) process, a Low Pressure Chemical Vapor Deposition (LPCVD) process, or a Reduced Pressure Chemical Vapor Deposition (RPCVD) process.

In some embodiments, preferably, the thickness of each of the dielectric layer and the amorphous silicon layer is in a range of 10 Å to 1000 Å (angstroms).

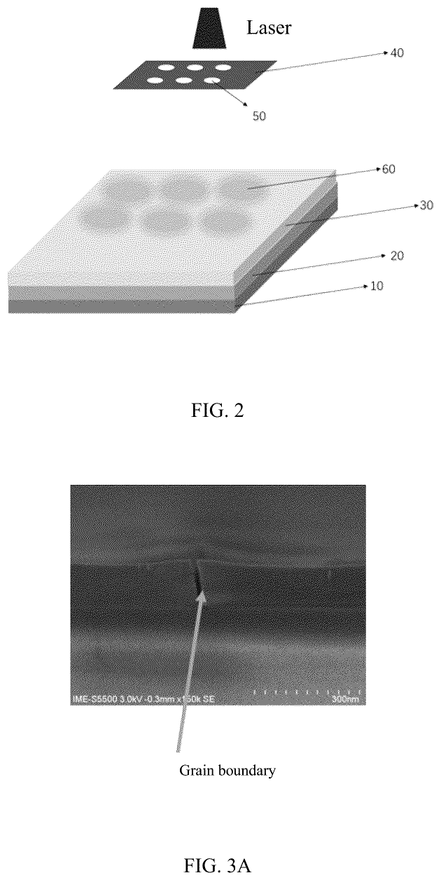

Step 102: a mask plate is irradiated by using the laser to perform a silicon crystallization in a partial region of the amorphous silicon layer, where a grain boundary of a polycrystalline silicon formed by the silicon crystallization in the partial region of the amorphous silicon layer is determined by a spacing between holes with a regular shape on the mask plate. FIG. 2 shows a schematic diagram of irradiating a mask plate by using a laser according to an embodiment of the present disclosure. As shown in FIG. 2, a mask plate 40 may have a plurality of circular holes 50, and partial amorphous silicon 60 on the amorphous silicon layer 30 is in a near-molten state by irradiating the mask plate 40 using a laser. When the partial amorphous silicon 60 is solidified in a near-molten state, it grows laterally to form a grain boundary of polycrystalline silicon, and the width of the grain boundary is determined by the spacing between the circular holes 50 on the mask plate 40.

It should be noted that: since the hole on the mask plate 40 is circular, and the partial amorphous silicon 60 in the near-molten state under the laser irradiation is also circular, the amorphous silicon 60 may grow uniformly in all directions. When the grown amorphous silicon touches each other, the growth stops, and a grain boundary between polycrystalline silicon is formed. Since the amorphous silicon 60 grows uniformly in all directions, when the circular holes on the mask plate are regularly distributed, the formed grain boundary of the polycrystalline silicon will present a regular rectangle. Therefore, preferably, the holes on the mask plate have a regular shape and the holes are regularly distributed.

In some embodiments, preferably, an energy density of the laser melting crystallization is in a range of 100 millijoules per square centimeter to 2 joules per square centimeter, which may be achieved by adjusting the laser power.

Step 103: a planarization process is performed on the grain boundary of the polycrystalline silicon of the amorphous silicon layer.

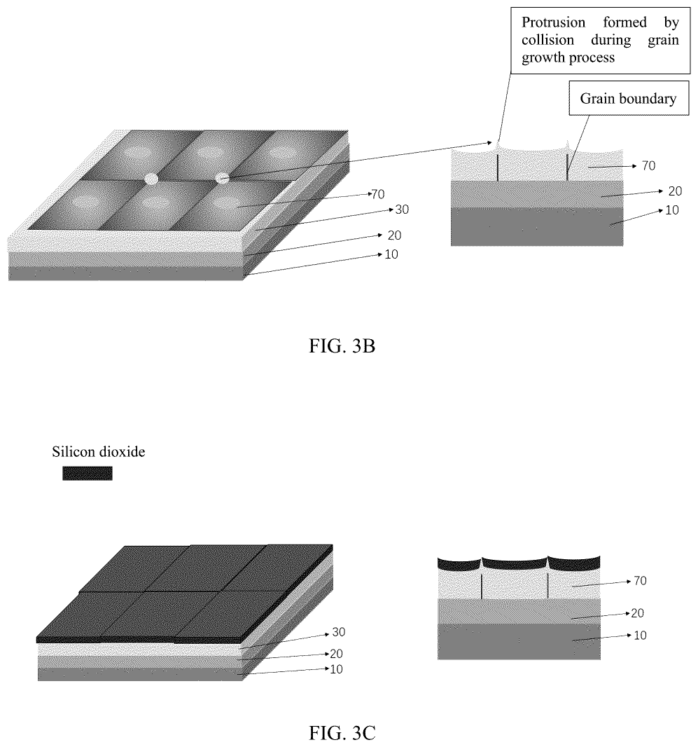

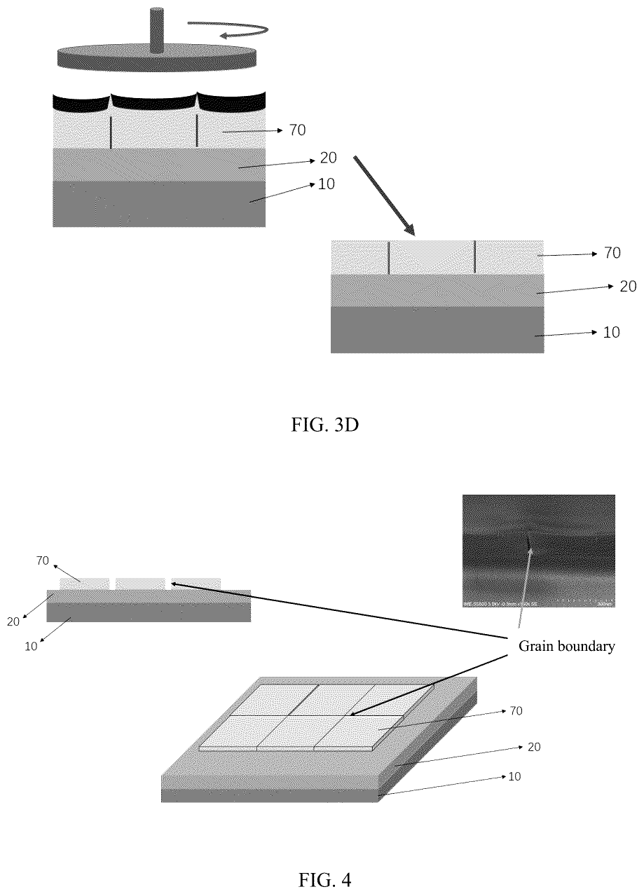

FIG. 3A shows an example of the grain boundary of the polycrystalline silicon formed in Step 102 according to an embodiment of the present disclosure. As shown in FIG. 3A, there may be a protrusion at the grain boundary of the polycrystalline silicon. In order to make the surface of the crystallized film smoother, the planarization process needs to be performed on the grain boundary of the polycrystalline silicon in Step 103.

In some preferred embodiments, performing a planarization process on the grain boundary of the polycrystalline silicon includes:
depositing a silicon dioxide on the amorphous silicon layer 30;
removing the silicon dioxide on the polycrystalline silicon by chemical mechanical polishing; and
removing the silicon dioxide on a surface of a remaining region of the amorphous silicon layer 30 by using an acidic corrosion solution.

In the above-mentioned embodiment, silicon dioxide with a thickness of 10 nm to 100 nm (nanometers) may be deposited on the amorphous silicon layer 30. Then, the surface of the crystallized film is planarized by using a chemical mechanical polishing process. Finally, silicon dioxide on the surface of the amorphous silicon layer 30 is corroded by using an acidic corrosion solution such as hydrofluoric acid.

The above-mentioned preferred embodiments will be described below with reference to FIG. 3B to FIG. 3D.

FIG. 3B shows another example of a grain boundary of polycrystalline silicon formed in Step 102 according to the present embodiment. As shown in FIG. 3B, the molten silicon will collide with the silicon grown from the adjacent direction during the lateral growth in all directions, causing the lateral growth to terminate and forming the grain boundary. The crystallized surface is not perfectly flat, and a series of protrusions are formed at the grain boundary position due to the collision caused by growth from the opposite directions. Therefore, it is desired to perform the planarization processing on the grain boundary of the polycrystalline silicon. FIG. 3C to FIG. 3D show a process flow of performing a planarization process on the grain boundary in FIG. 3B.

FIG. 3C shows a conceptual diagram of a structure after depositing silicon dioxide on an amorphous silicon layer 30. The thickness of the deposited silicon dioxide in FIG. 3C may be in a range of 10 nm to 100 nm (nanometers).

FIG. 3D shows a conceptual diagram of a structure after removing silicon dioxide on the polycrystalline silicon 70 by using a chemical mechanical polishing process. Through the chemical mechanical polishing, the protrusion may be removed and the surface may be ground flat.

In the process shown in FIG. 3C, since silicon dioxide is also deposited on a surface of the remaining region (i.e., the surface region outside the polycrystalline silicon 70) of the amorphous silicon layer 30, the following process will be performed next: removing the silicon dioxide on a surface of a remaining region of the amorphous silicon layer 30 by using an acidic corrosion solution.

Step 104: the grain boundary is removed by using a corrosion solution to form a grain boundary trench.

In this embodiment, the grain boundary corrosion may be performed by using the Secco corrosion solution (the main material is a mixture of potassium dichromate, hydrofluoric acid and water).

It should be noted that the Secco corrosion solution may corrode amorphous silicon. Since the crystal orientation in the grain boundary is not uniform, the grain boundary is also a type of amorphous silicon. When the grain boundary corrosion is performed by using the Secco corrosion solution, the amorphous silicon layer 30 is also corroded off, leaving the polycrystalline silicon 70.

FIG. 4 shows an example of a planarized grain boundary of the polycrystalline silicon according to the above-mentioned preferred embodiments. By removing the grain boundary protrusion formed in the laser crystallization process, the obtained grain boundary may be smoother and more regular.

Step 105: the nanoscale line is obtained on the substrate by using the grain boundary trench.

In this embodiment, the trench with the Damascus structure is obtained by corroding and removing the grain boundary, and the minimum size of the trench may reach the nanometer level.

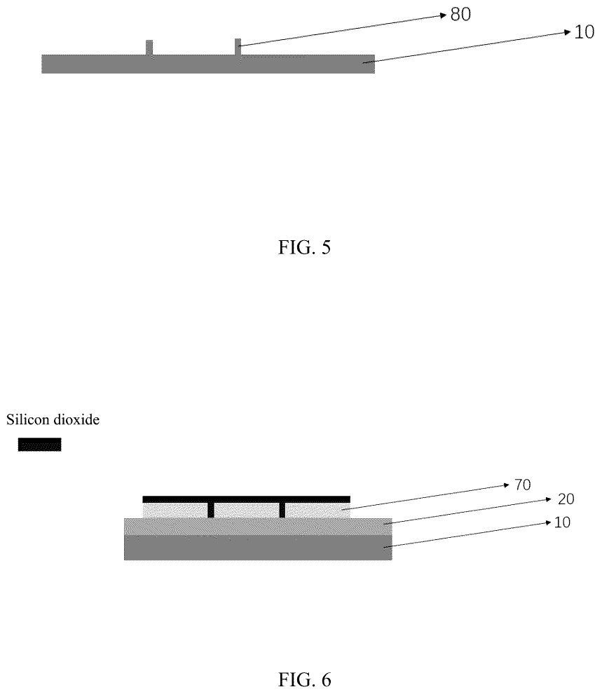

FIG. 5 shows an example of a nanoscale line obtained on a substrate according to an embodiment of the present disclosure. As shown in FIG. 5, a material of the fine line 80 is the same as the material of the substrate 10, and a width of fine line 80 is determined by the width of the grain boundary trench of polycrystalline silicon.

Compared with the related art, in the method of obtaining the nanoscale line by using the laser provided by this embodiment, the low-cost nanoscale line array may be obtained by using the regular grain boundary formed by a laser crystallization method and a Damascus process, and may be used for an integrated circuit preparation process less than 5 nanometers after integration.

In some embodiments, the material of the dielectric layer in Step 101 may be silicon nitride. The silicon wettability of the silicon nitride material is good, which may reduce a nucleation rate in the crystallization process and promote a lateral growth.

In some embodiments, the material of the substrate in Step 101 may be silicon or silicon dioxide. Previously, the Damascus structure is mainly used for the metal interconnection process, which has a large size and relies heavily on the photolithography machine. In the above-mentioned technical solution, the Damascus structure is used to obtain the hard mask material for the fine line. The trench with the Damascus structure is obtained by corroding and removing the grain boundary, and the minimum size of the trench may be less than 20 nanometers, which is equivalent to an extreme ultraviolet photolithography machine.

In some embodiments, Step 105 may include the following steps S10 to S50.

S10: a silicon dioxide film is filled on the polycrystalline silicon 70 to cover the grain boundary trench; the silicon dioxide is deposited on the polycrystalline silicon 70 to fill the entire grain boundary trench.

In this embodiment, the silicon dioxide may be deposited on the polycrystalline silicon 70 to fill the entire grain boundary trench. FIG. 6 shows a conceptual diagram of a structure after filling a silicon dioxide film on the polycrystalline silicon 70 to cover the grain boundary trench. In some embodiments, an Atomic Layer Deposition (ALD) process may be used to fill the grain boundary trench with silicon dioxide, and the height of the silicon dioxide is higher than the trench and a layer of silicon dioxide film is formed on the polycrystalline silicon. It should be noted that, since the grain boundary trench of the polycrystalline silicon 70 may reach the nanometer level, silicon dioxide is filled by using the ALD process preferably.

S20: the silicon dioxide on a surface of the polycrystalline silicon 70 is removed by chemical mechanical polishing or reverse etching.

In this embodiment, the silicon dioxide film on the polycrystalline silicon 70 may be removed by chemical mechanical polishing or reverse etching, so as to expose the upper portion of the polycrystalline silicon.

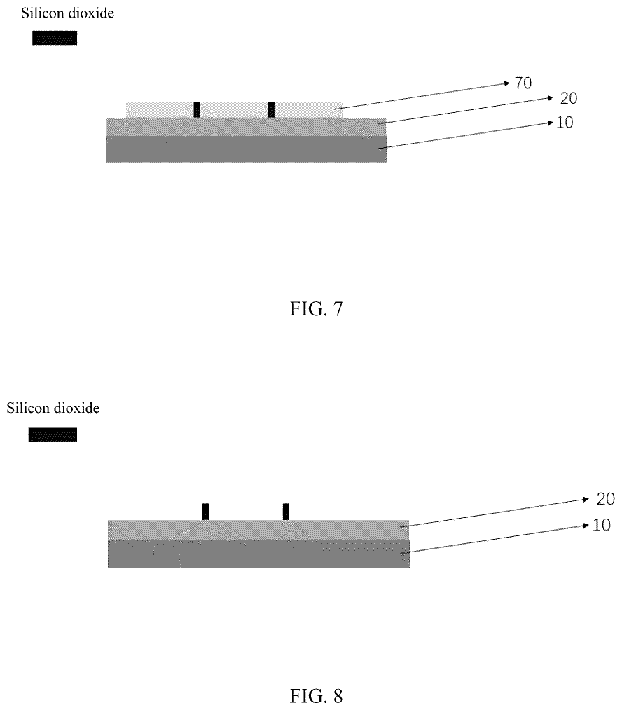

FIG. 7 shows a conceptual diagram of a structure after removing silicon dioxide on a surface of the polycrystalline silicon 70 by chemical mechanical polishing or reverse etching.

S30: the polycrystalline silicon 70 is removed by using an alkaline silicon corrosion solution, and the silicon dioxide filled in the grain boundary trench is retained.

FIG. 8 shows a conceptual diagram of a structure after removing the polycrystalline silicon 70 by using an alkaline silicon corrosion solution. In some embodiments, the alkaline silicon corrosion solution may be a tetramethylammonium hydroxide solution or a potassium hydroxide solution.

S40: the dielectric layer 20 is etched by using the silicon dioxide in the grain boundary trench as a hard mask, and the etching stops at a surface of the substrate 10.

In this embodiment, the dielectric layer 20 may be etched by using silicon dioxide in the grain boundary trench as a hard mask, so as to expose the substrate 10.

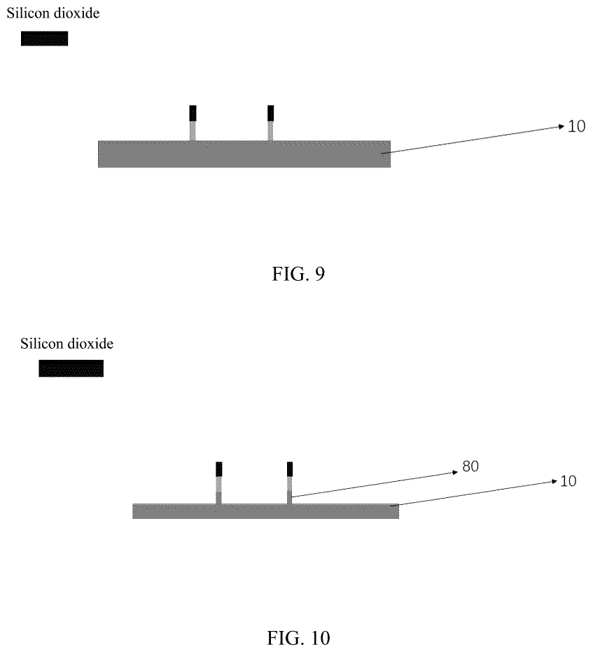

FIG. 9 shows a conceptual diagram of a structure after etching the dielectric layer 20 by using the silicon dioxide in the grain boundary trench as a hard mask.

S50: the substrate 10 is etched by using the silicon dioxide in the grain boundary trench and the etched dielectric layer 20 as a hard mask, so as to obtain the nanoscale line.

In this embodiment, the substrate 10 may be etched by using silicon dioxide in the grain boundary trench and the dielectric below the silicon dioxide as a hard mask, so as to obtain the nanoscale line, and the substrate with a partial height may be retained.

FIG. 10 shows a conceptual diagram of a structure after etching the substrate 10 by using the silicon dioxide in the grain boundary trench and the etched dielectric layer 20 as a hard mask to obtain the nanoscale line.

In the embodiments described above in combination with Step S10 to Step S50, after the grain boundary trench is filled, the filled material in the grain boundary trench may be used as a hard mask material for subsequent pattern transfer, and the thickness of the hard mask material is mainly determined by the thickness of the polycrystalline silicon film, which is unlike the photolithography process, i.e. the thickness of the photoresist decreases with the decrease of the line width.

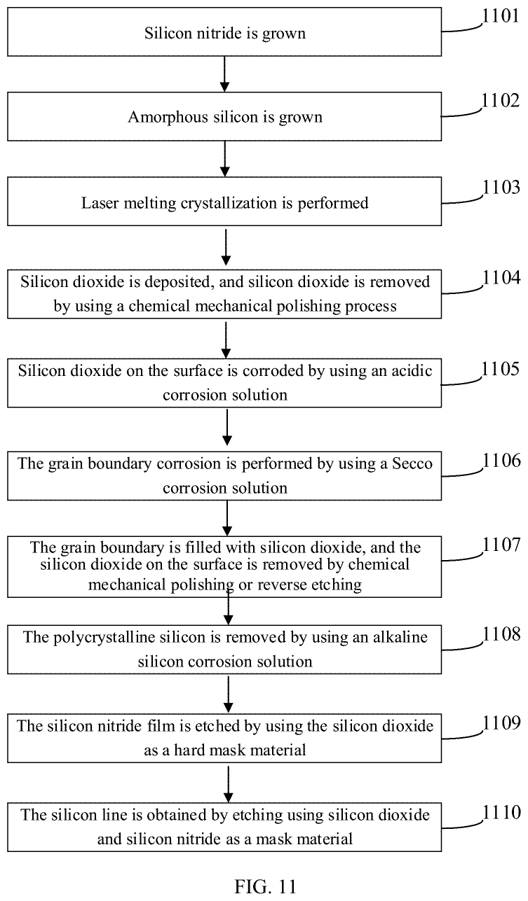

FIG. 11 shows a process flow of a method of obtaining a nanoscale line by using a laser according to an embodiment of the present disclosure. The following description is made with reference to FIG. 11.

As shown in FIG. 11, in Step 1101, silicon nitride is grown, where a thickness of silicon nitride may be in a range of 10 Å to 1000 Å (angstroms). In Step 1102, amorphous silicon is grown, where a thickness of amorphous silicon may be in a range of 10 Å to 1000 Å (angstroms), and PECVD, LPCVD, RPCVD, and the like may be used. In Step 1103, laser melting crystallization may be performed by irradiating the mask plate with a laser, where an energy density of the laser is in a range of 100 millijoules per square centimeter to 2 joules per square centimeter. In Step 1104, silicon dioxide is deposited, and silicon dioxide is removed by using a chemical mechanical polishing process. In Step 1105, silicon dioxide on the surface is corroded by using an acidic corrosion solution. In Step 1106, the grain boundary corrosion is performed by using a Secco corrosion solution. In Step 1107, the grain boundary is filled with silicon dioxide and the silicon dioxide on the surface is removed by chemical mechanical polishing or reverse etching. In Step 1108, the polycrystalline silicon is removed by using an alkaline silicon corrosion solution. In Step 1109, the silicon nitride film is etched by using the silicon dioxide as a hard mask material. In Step 1110, the silicon line is obtained by etching using silicon dioxide and silicon nitride as a mask material.

The embodiments described above with reference to FIG. 11 have at least the following beneficial technical effects:
1. The low-cost nanoscale line array may be obtained by using the regular grain boundary formed by a laser crystallization method and a Damascus process, and may be used for an integrated circuit preparation process less than 5 nanometers after integration.
2. Previously, the Damascus structure is mainly used for the metal interconnection process, which has a large size and relies heavily on the photolithography machine. In the above-mentioned technical solution, the Damascus structure is used to obtain the hard mask material for the fine line. The trench with the Damascus structure is obtained by corroding and removing the grain boundary, and the minimum size of the trench may be less than 20 nanometers, which is equivalent to an extreme ultraviolet photolithography machine.
3. After the grain boundary trench is filled, the filled material in the grain boundary trench may be used as a hard mask material for subsequent pattern transfer, and the thickness of the hard mask material is mainly determined by the thickness of the film, which is unlike the photolithography process, i.e. the thickness of the photoresist decreases with the decrease of the line width.

The above description is only preferred embodiments of the present disclosure, but the protection scope of the present disclosure is not limited thereto. Within the technical scope disclosed by the present disclosure, any changes or substitutions that may be easily conceived by those skilled in the art should be included in the protection scope of the present disclosure.

What is claimed is:

1. A method of obtaining a nanoscale line by using a laser, comprising:
forming a dielectric layer and an amorphous silicon layer on a substrate sequentially;
irradiating a mask plate by using the laser to perform a silicon crystallization in a partial region of the amorphous silicon layer, wherein a grain boundary of a polycrystalline silicon formed by the silicon crystallization in the partial region of the amorphous silicon layer is determined by a spacing between holes with a regular shape on the mask plate;
performing a planarization process on the grain boundary of the polycrystalline silicon of the amorphous silicon layer;
removing the grain boundary by using a corrosion solution to form a grain boundary trench; and
obtaining the nanoscale line on the substrate by using the grain boundary trench.

2. The method according to claim 1, wherein a material of the dielectric layer is silicon nitride.

3. The method according to claim 1, wherein a material of the substrate is silicon or silicon dioxide.

4. The method according to claim 1, wherein the performing a planarization process on the grain boundary of the polycrystalline silicon of the amorphous silicon layer comprises:
depositing a silicon dioxide on the amorphous silicon layer;
removing the silicon dioxide on the polycrystalline silicon by chemical mechanical polishing; and
removing the silicon dioxide on a surface of a remaining region of the amorphous silicon layer by using an acidic corrosion solution.

5. The method according to claim 1, wherein the obtaining the nanoscale line on the substrate by using the grain boundary trench comprises:
filling a silicon dioxide film on the polycrystalline silicon to cover the grain boundary trench;
removing the silicon dioxide on a surface of the polycrystalline silicon by chemical mechanical polishing or reverse etching;
removing the polycrystalline silicon by using an alkaline silicon corrosion solution and retaining the silicon dioxide filled in the grain boundary trench;
etching the dielectric layer by using the silicon dioxide in the grain boundary trench as a hard mask, and stopping the etching at a surface of the substrate; and
etching the substrate by using the silicon dioxide in the grain boundary trench and the etched dielectric layer as a hard mask, so as to obtain the nanoscale line.

6. The method according to claim 5, wherein the filling a silicon dioxide film on the polycrystalline silicon to cover the grain boundary trench comprises:
filling, by using an atomic layer deposition ALD process, the silicon dioxide film on the polycrystalline silicon to cover the grain boundary trench.

7. The method according to claim 5, wherein the alkaline silicon corrosion solution is a tetramethylammonium hydroxide solution or a potassium hydroxide solution.

8. The method according to claim 1, wherein a width of the nanoscale line is less than 10 nanometers.

9. The method according to claim 5, wherein a width of the nanoscale line is less than 10 nanometers.

10. The method according to claim 1, wherein the corrosion solution is a Secco corrosion solution.

11. The method according to claim 5, wherein the corrosion solution is a Secco corrosion solution.

12. The method according to claim 1, wherein an energy density of the laser is in a range of 100 millijoules per square centimeter to 2 joules per square centimeter.

13. The method according to claim 5, wherein an energy density of the laser is in a range of 100 millijoules per square centimeter to 2 joules per square centimeter.
